(19) United States
(12) Patent Application Publication
(10) Pub. No.: US 2020/0107469 A1
(43) Pub. Date: Apr. 2, 2020

(54) WIRELESS CHARGING DEVICE WITH HEAT DISSIPATION FUNCTION

(71) Applicant: ADATA TECHNOLOGY CO., LTD., NEW TAIPEI CITY (TW)

(72) Inventors: CHI-WEN CHOU, New Taipei City (TW); Jen-Chieh Pan, New Taipei City (TW)

(21) Appl. No.: 16/190,875

(22) Filed: Nov. 14, 2018

(30) Foreign Application Priority Data
Sep. 28, 2018 (TW) 107134389

(51) Int. Cl. H05K 7/20; H02J 7/02; H05K 7/14; H02J 7/00; H05K 5/02

(52) U.S. Cl. CPC H05K 7/20236; H02J 7/025; H05K 5/0247; H05K 7/1427; H02J 7/0042; H05K 7/20927

(57) ABSTRACT

A wireless charging device with a heat dissipation function is provided. The wireless charging device includes a case, a wireless charging assembly and a working fluid. The case includes an accommodation space. The wireless charging assembly is disposed in the accommodation space. The wireless charging assembly includes a circuit board, a coil coupled to the circuit board and a connector coupled to the circuit board. The working fluid is disposed in the accommodation space in the case. The circuit board and the coil of the wireless charging assembly are immersed in the working fluid.

### CROSS-REFERENCE TO RELATED PATENT APPLICATION

This application claims the benefit of priority to Taiwan Patent Application No. 107134389, filed on Sep. 28, 2018. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a wireless charging device, and more particularly to a wireless charging device with a heat dissipation function.

### BACKGROUND OF THE DISCLOSURE

The charging efficiency of a wireless charging device is closely related to the operating temperature. When the operating temperature is too high, the efficiency of wireless charging is deteriorated or the protection scheme of the circuit board is activated so that the wireless charging device cannot continuously charge. Therefore, the electronic device to be charged requires more time to charge or is unable to continuously receive electrical energy.

In the conventional art, the temperature of the integrated circuit (IC) in the wireless charging device is lowered by using a fan, a convection hole, a thermal grease, a thermal paste, a copper heat sink, or changing the material of the case or providing fins. However, the effect of heat dissipation of the wireless charging device by using the above methods is still limited. In addition, the inclusion of fans or fins may result in a significant increase in cost. Therefore, in order to overcome the above issues, how the efficiency in heat dissipation of the wireless charging device can be improved has become one of the important issues to be solved in the art.

### SUMMARY OF THE DISCLOSURE

In response to the above-referenced technical inadequacies, the present disclosure provides a wireless charging device with a heat dissipation function.

In one aspect, the present disclosure provides a wireless charging device with a heat dissipation function. The wireless charging device includes: a case, a wireless charging assembly and a working fluid. The case includes an accommodation space. The wireless charging assembly is disposed in the accommodation space. The wireless charging assembly includes a circuit board, a coil coupled to the circuit board and a connector coupled to the circuit board. The working fluid is disposed in the accommodation space of the case. The circuit board and the coil of the wireless charging assembly are immersed in the working fluid.

Therefore, one of the beneficial effects of the present disclosure is that, with the technical solution of “the working fluid is disposed in the accommodation space of the case and the circuit board and the coil of the wireless charging assembly are immersed in the working fluid,” the wireless charging device with the heat dissipation function provided by the present disclosure can improve the efficiency in heat dissipation of the wireless charging device, and the efficiency of continuous charging of the wireless charging device.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a perspective view of a wireless charging device with a heat dissipation function according to a first embodiment of the present disclosure.

FIG. 2 is an exploded view of the wireless charging device according to the first embodiment of the present disclosure.

FIG. 3 is an exploded view of the wireless charging device according to the first embodiment of the present disclosure.

FIG. 4 is an exploded view of the wireless charging device according to the first embodiment of the present disclosure. FIG. 5 is an exploded view of the wireless charging device according to the first embodiment of the present disclosure.

FIG. 6 is a partially enlarged view of FIG. 2.

FIG. 7 is a cross-sectional view taken along line VII-VII of FIG. 1.

FIG. 8 is a partially enlarged view of FIG. 7.

FIG. 9 is a schematic view of a wireless charging device with a heat dissipation function in use according to a second embodiment of the present disclosure.

FIG. 10 is a schematic view of the wireless charging device in use according to the second embodiment of the present disclosure.

FIG. 11 is a perspective view of a wireless charging device with a heat dissipation function according to a third embodiment of the present disclosure.

FIG. 12 is an exploded view of the wireless charging device according to the third embodiment of the present disclosure.

FIG. 13 is a perspective view of a wireless charging device with a heat dissipation function according to a fourth embodiment of the present disclosure.

FIG. 14 is an exploded view of the wireless charging according to the fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

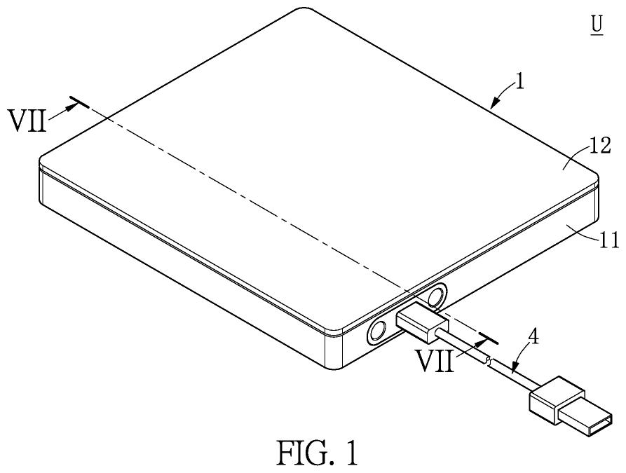

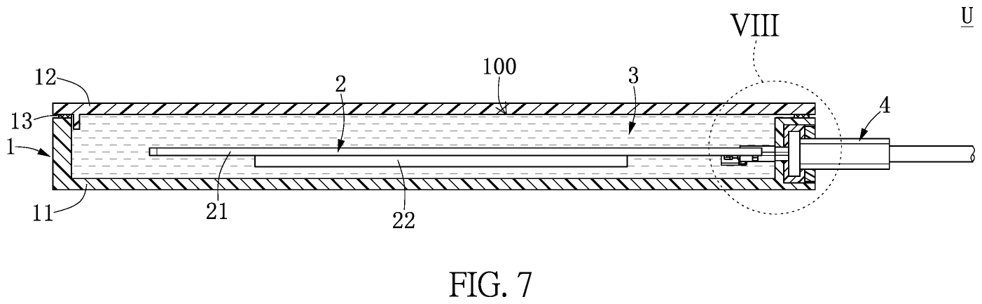

Referring to FIG. 1 and FIG. 7, FIG. 1 is a perspective view of a wireless charging device with a heat dissipation function according to a first embodiment of the present disclosure, and FIG. 7 is a cross-sectional view taken along line VII-VII of FIG. 1. The present disclosure provides a wireless charging device U with a heat dissipation function. The wireless charging device U includes a case 1, a wireless charging assembly 2 and a working fluid 3. Preferably, the wireless charging device U may further include a cable assembly 4 connected between the wireless charging assembly 2 and the commercial power to supply the electrical energy of the commercial power to the wireless charging assembly 2. Accordingly, the wireless charging assembly 2 transmits electrical energy to an electronic device (not shown, such as but not limited to a smartphone) by means of electromagnetic induction, magnetic resonance or electric field coupling.

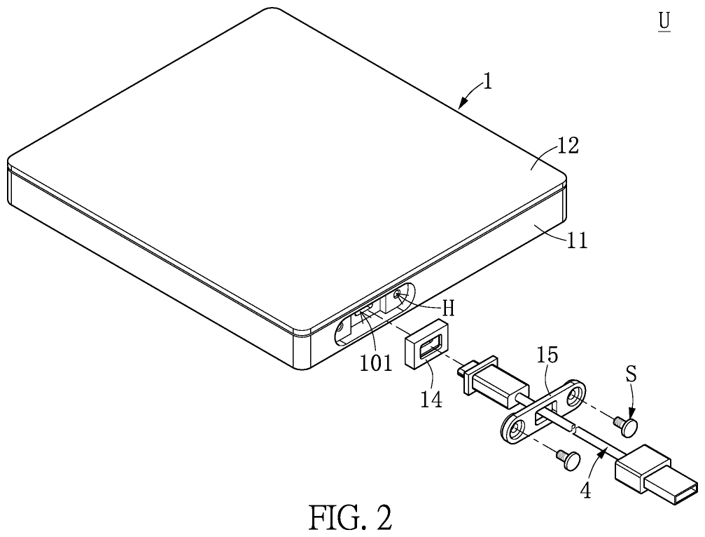

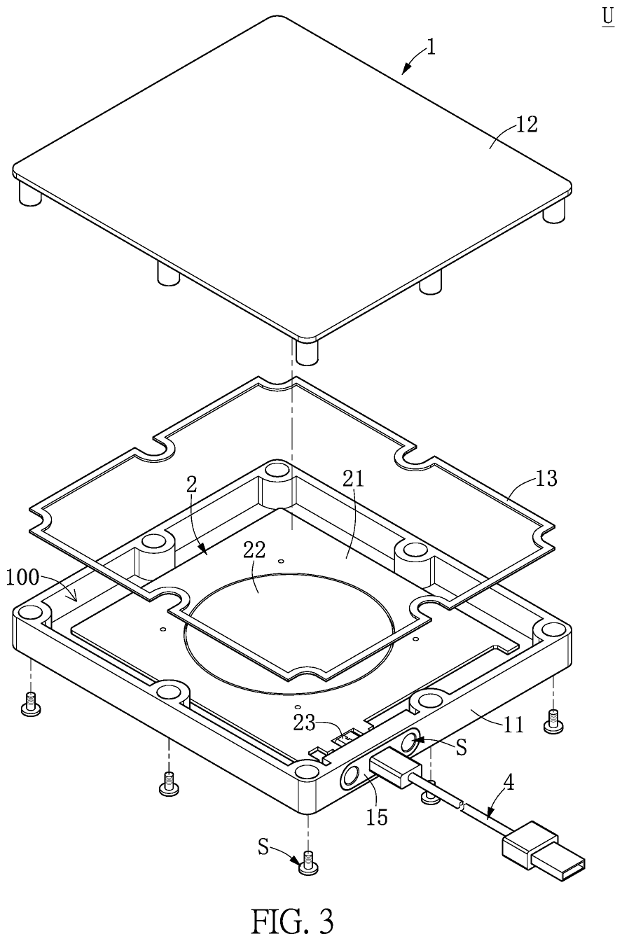

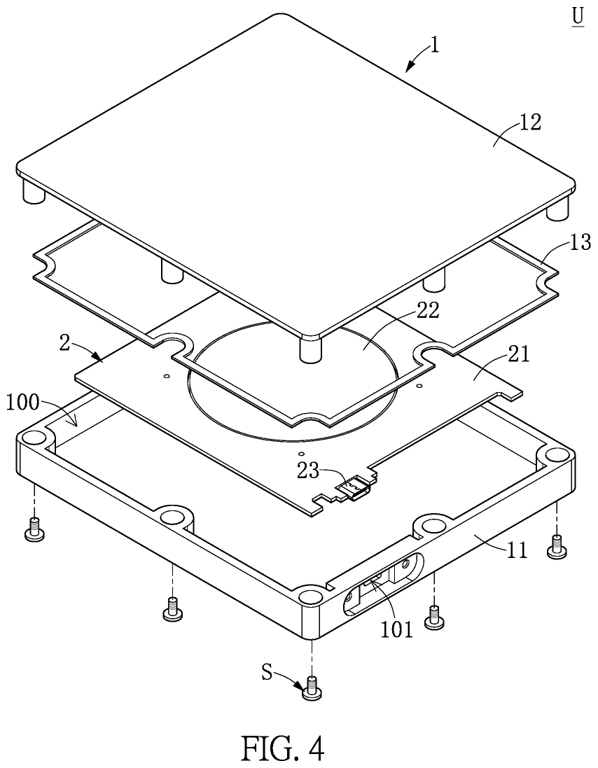

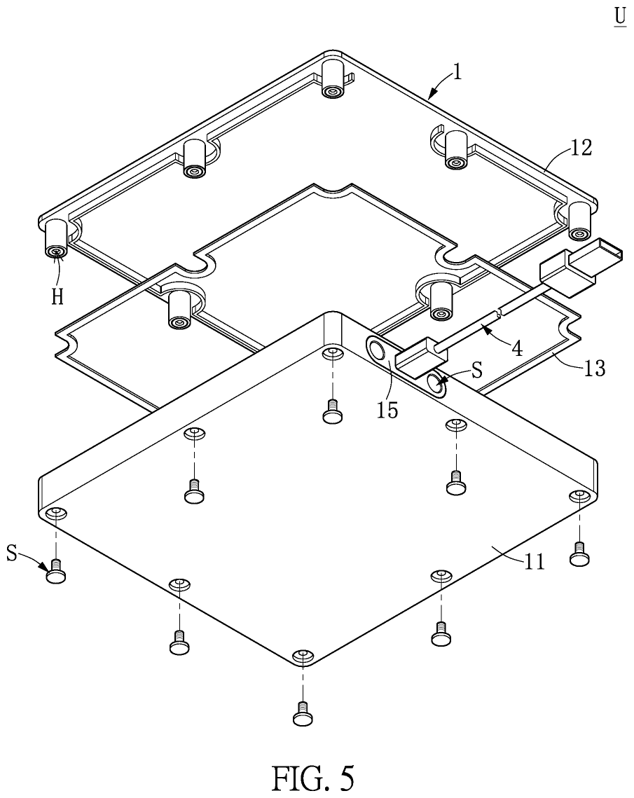

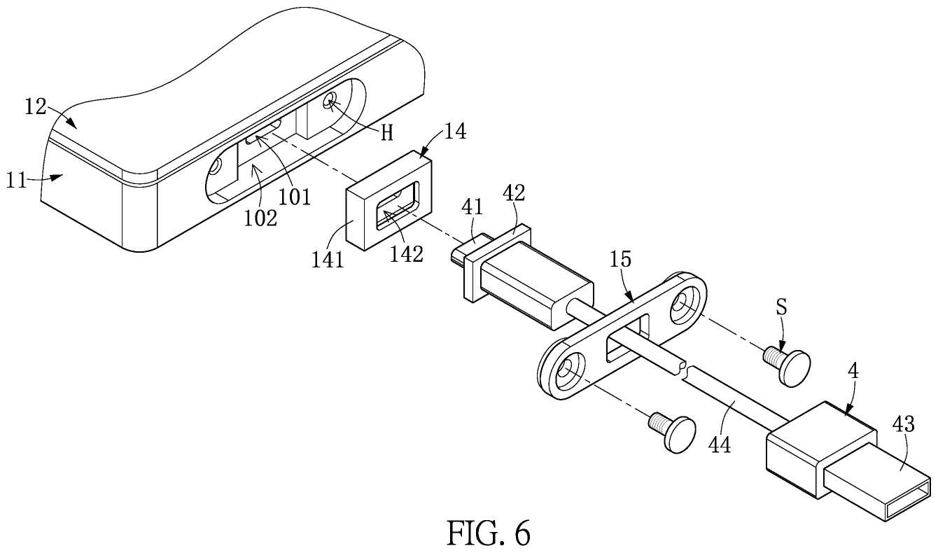

Referring again to FIG. 1 and FIG. 7, and in conjunction with FIG. 2 to FIG. 6, FIG. 2 to FIG. 5 are exploded views of the wireless charging device according to the first embodiment of the present disclosure, and FIG. 6 is a partially enlarged view of FIG. 2. The case 1 includes an accommodation space 100. The wireless charging assembly 2 and the working fluid 3 are disposed in the accommodation space 100 and the wireless charging assembly 2 is immersed in the working fluid 3. For example, in the first embodiment, the case 1 includes a first case 11 and a second case 12. The accommodation space 100 is formed between the first case 11 and the second case 12. Preferably, the case 1 may further include a gasket 13 disposed between the first case 11 and the second case 12 to improve the adhesion between the first case 11 and the second case 12, thereby preventing the working fluid 3 from leaking out. The material of the gasket 13 may have flexibility, such as but not limited to rubber. It is worth mentioning that the first case 11 and the second case 12 can be combined by a cooperation of a lock fastener S and a locking hole H. However, in other embodiments, the first case 11 and the second case 12 may be combined by gluing (with, such as but not limited to a glue dispensing machine, which is not shown). Moreover, in other embodiments, the first case 11 and the second case 12 may be combined by being buckled together (not shown). The present disclosure is not limited to the manner of combination of the first case 11 and the second case 12, as long as the first case 11 is combined with the second case 12 and the working fluid 3 is prevented from leaking out. In other words, the case 1 may be a closed case to seal in the working fluid 3. Accordingly, heat generated by the wireless charging assembly 2 is conducted by the working fluid 3 to the case 1, and is dissipated to the external environment through the case 1.

Based on the above, referring again to FIG. 1 to FIG. 7, the wireless charging assembly 2 includes a circuit board 21, a coil 22 coupled to the circuit board 21 and a connector 23 coupled to the circuit board 21. The circuit board 21 and the coil 22 of the wireless charging assembly 2 are immersed in the working fluid 3. Accordingly, heat generated by the circuit board 21 and the coil 22 of the wireless charging assembly 2 is conducted to the case 1 by the working fluid 3, and thus the efficiency of heat dissipation is improved. In other words, in the embodiment of the present disclosure, the circuit board 21 and the coil 22 of the wireless charging assembly 2 directly contact the working fluid 3. The working fluid 3 may be packaged (or closed or sealed) in the accommodation space 100 of the case 1 and the working fluid 3 is not in contact with the external environment. Furthermore, the first case 11 and the second case 12 may be made of metal, non-metal or plastic, and the present disclosure is not limited thereto. It is worth mentioning that although the wireless charging assembly 2 is exemplified by the circuit board 21, the coil 22 and the connector 23, the present disclosure is not limited thereto. In other words, the structural configuration of the wireless charging assembly 2 is well known to those skilled in the art, and will not be described in detail herein. Furthermore, it is worth mentioning that in the first embodiment, the wireless charging assembly 2 is disposed on the first case 11 of the case 1. For example, a lock fastener (not shown in the drawings) is used to fixedly position the wireless charging assembly 2, but the present disclosure is not limited to the form in which the wireless charging assembly 2 is disposed in the case 1.

Again, referring to FIG. 1 to FIG. 7 in conjunction with FIG. 8, FIG. 8 is a partially enlarged view of FIG. 7. In the first embodiment, the cable assembly 4 includes a connecting terminal 41 and a buckle portion 42 near the connecting terminal 41, and the connecting terminal 41 is coupled to the connector 23. For instance, the connecting terminal 41 may be inserted in the connector 223, but the present disclosure is not limited thereto. Further, the cable assembly 4 may further include a power terminal 43 and a cable body 44. The connecting terminal 41 and the power terminal 43 can be respectively connected to the two ends of the cable body 44. Further, the connecting terminal 41 may be connected to the connector 23 of the wireless charging assembly 2, and the power terminal 43 may be connected to the commercial power. It should be stated that the present disclosure is not limited to the manner of connection between the connecting terminal 41 and the connector 23 as long as the connecting terminal 41 can be coupled to the connector 23 and the commercial power can be transmitted to the wireless charging assembly 2. It is worth mentioning that although the power terminal 43 in the drawings is exemplified as a universal serial bus (USB), in other embodiments, the power terminal 43 may be a domestic mains plug, and the present disclosure is not limited thereto.

Based on the above, referring again to FIG. 1 to FIG. 8, the first case 11 of the case 1 includes a slot body 101 and a slot 102, and the slot body 101 is disposed in the slot 102. The connecting terminal 41 of the cable assembly 4 is inserted in the slot body 101 so that the cable assembly 4 passes through the slot body 101 and is coupled to the connector 23 of the wireless charging assembly 2. In addition, the case 1 may further include a first cover body 14 and a second cover body 15. The first cover body 14 and the second cover body 15 are disposed in the slot 102 and the first cover body 14 includes a main body 141 and an opening slot 142 disposed on the main body 141. It is worth mentioning that the first cover body 14 is flexible. Therefore, the buckle portion 42 of the cable assembly 4 is disposed in the opening slot 142 on the first cover body 14, so that the first cover body 14 is disposed on the cable assembly 4. It is worth mentioning that in other embodiments, the first cover body 14 may also be integrally formed with the buckle portion 42 of the cable assembly 4, and the present disclosure is not limited thereto. Further, the second cover body 15 is abutted against the first cover body 14 to be indirectly abutted against the cable assembly 4. Accordingly, the cable assembly 4 may be fixedly positioned on the case 1 through the first cover body 14 and the second cover body 15. It is worth mentioning that in the first embodiment, the first case 11 of the case 1 includes the locking hole H, and the lock fastener S corresponding to the locking hole H to fixedly position the second cover body 15 in the case 1. Further, since the first cover body 14 is flexible, the first cover body 14 is deformed by the pressing of the second cover body 15 so that the second cover body 15 also has the effect of avoiding leakage of the working fluid 3.

Referring again to FIG. 7, the working fluid 3 may be an insulating liquid or a dielectric liquid having an effect of heat conduction, for example, a liquid having the boiling point lower than 76° C.; preferably, a liquid having the boiling point lower 65° C.; and more specifically, a liquid having hydrofluoroether. That is, the present disclosure may use a pure compound or an azeotropic mixture, such as an electron fluorinated liquid and a fluorine solution, having a boiling point of 62° C., 55° C. or 48° C., to serve as the working fluid 3, but is not limited thereto. Further, in one embodiment, the working fluid 3 can be the 3M™ Novec™ Engineered Fluid and the model number can be 7100 Engineered Fluid, 7200 Engineered Fluid, 7300 Engineered Fluid or 7500 Engineered Fluid, and the present disclosure is not limited thereto. Further, the working fluid 3 may be the 3M™ Fluorinert™ Electronic Liquid, but the present disclosure is not limited thereto.

Based on the above, as the wireless charging assembly 2 is directly in contact with the working fluid 3, the heat generated by the wireless charging assembly 2 during operation is first transmitted to the working fluid 3, and then transmitted to the case 1. It is worth mentioning that when the working fluid 3 is a liquid having a low boiling point, the working fluid 3 is easily boiled by being heated. Consequently, the working fluid 3 rises in temperature and reaches the boiling point. The working fluid 3 can change phases from a liquid state to a gaseous state by using the received thermal energy. A large amount of heat is consumed during the phase change, which is helpful to improve the efficiency of heat dissipation of the wireless charging assembly 2. In addition, during the aforementioned phase change of the working fluid 3 from the liquid state to the gaseous state, the working fluid 3 generates convection in the accommodation space 100, and the working fluid 3 that changes from the liquid state to the gaseous state forms air bubbles to disturb the working fluid 3, resulting in the boiling phenomenon.

According to the above, the working liquid 3 may have a volume of 40% to 100% of the accommodation space 100 disposed with the wireless charging assembly 2, for example. However, the present disclosure is not limited thereto. It is worth mentioning that in one embodiment, when the material of the case 1 is a colorless translucent body made of polycarbonate (PC) resin, a user can directly observe the boiling of the working liquid 3 with the naked eye to easily confirm the condition of the heat dissipation.

### Second Embodiment

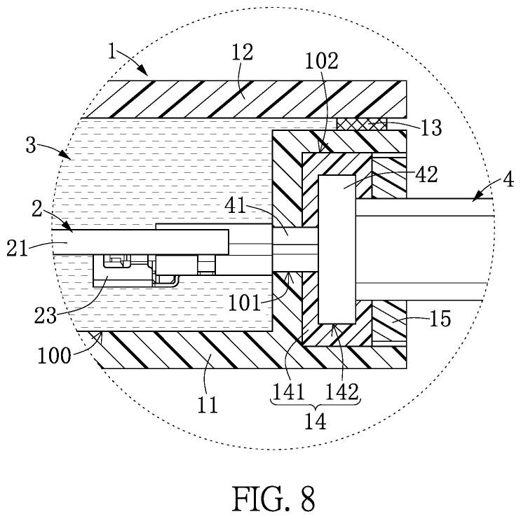

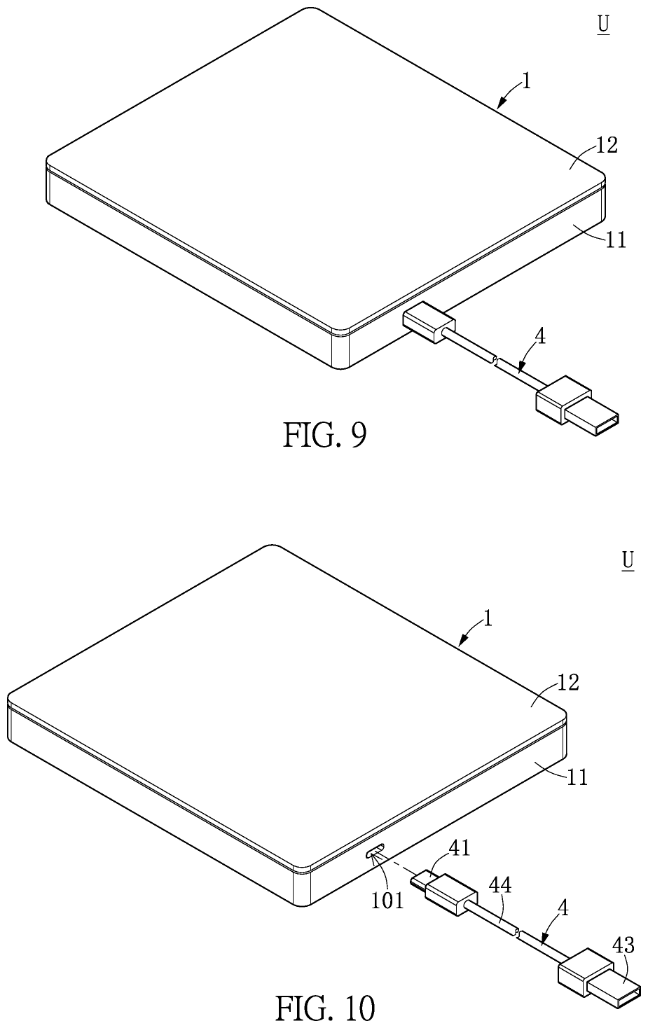

Referring to FIG. 9 and FIG. 10, FIG. 9 and FIG. 10 are schematic views of a wireless charging device with a heat dissipation function in use according to a second embodiment of the present disclosure. Comparing FIG. 10 and FIG. 2, the most obvious difference between the second embodiment and the first embodiment is that, the structural design of the case 1 of the wireless charging device U with the heat dissipation function provided by the second embodiment is different from that of the aforementioned first embodiment. That is to say, the case 1 of the wireless charging device U with the heat dissipation function provided by the second embodiment may not include the first cover body 14 and the second cover body 15, and the cable assembly 4 may not include the buckle portion 42.

Further, the case 1 includes the slot body 101. The connector 23 of the wireless charging assembly 2 is exposed through the slot body 101 of the case 1. The connecting terminal 41 of the cable assembly 4 is pluggably disposed in the slot body 101 so that the cable assembly 4 is coupled to the connector 23 of the wireless charging assembly 2 through the slot body 101. Accordingly, in the second embodiment, since the accommodation space 100 is a closed space, and the working fluid 3 is packaged in the accommodation space 100 of the case 1, when the cable assembly 4 is pulled out of the slot body 101, the working fluid 3 does not leak out from the slot body 101. Therefore, when the cable assembly 4 is damaged, the user can replace the cable assembly 4 by him/herself.

Based on the above, it is worth mentioning that in the second embodiment, the case 1 may be composed of the first case 11, the second case 12 and the gasket 13, but the present disclosure is not limited thereto. Also, the technique for preventing the working fluid 3 from leaking out is well known to those skilled in the art, and should be omitted therein. It should be noted that the structures of the case 1, the wireless charging assembly 2, the working fluid 3 and the cable assembly 4 are similar to those in the above embodiment, and will be omitted therein.

### Third Embodiment

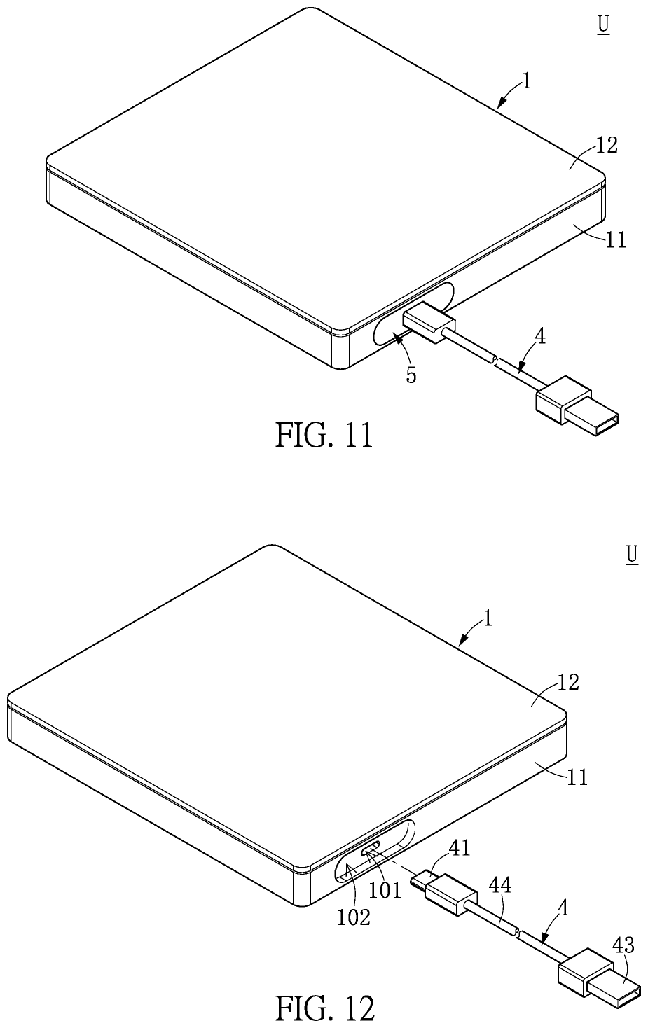

Referring to FIG. 11 and FIG. 12, FIG. 11 and FIG. 12 are respectively a perspective view and an exploded view of a wireless charging device with a heat dissipation function according to a third embodiment of the present disclosure. Comparing FIG. 11 and FIG. 2, the most obvious difference between the third embodiment and the first embodiment is that, the cable assembly 4 in the wireless charging device U with the heat dissipation function provided by the third embodiment uses a package 5 to be fixedly positioned on the case 1. It should be stated that the structures of the case 1, the wireless charging assembly 2, the working fluid 3 and the cable assembly 4 are similar to those in the aforementioned embodiment, and will be omitted therein.

Referring again to FIG. 11 and FIG. 12, the case 1 includes the slot body 101 and the slot 102, the cable assembly 4 is coupled to the connector 23 through the slot body 101. In addition, the package 5 is disposed in the slot 102 to cover the slot body 101 and a portion of the cable assembly 4. Accordingly, the package 5 may further provide a sealing effect between the connecting terminal 41 of the cable assembly 4 and the slot body 101 so as to prevent the working fluid 3 from leaking out. In addition, the package 5 may be formed by a colloid. After solidification, the colloid may be used to seal the connecting terminal 41 and the slot body 101, and also, to fixedly position the cable assembly 4.

### Fourth Embodiment

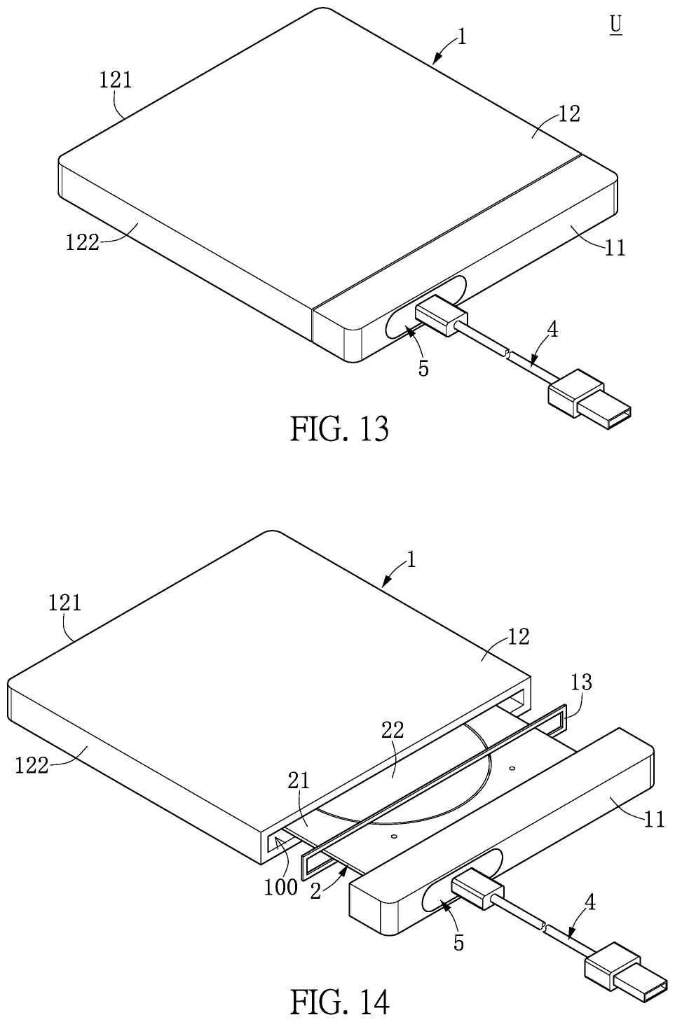

Referring to FIG. 13 and FIG. 14, FIG. 13 and FIG. 14 are respectively a perspective view and an exploded view of a wireless charging device with a heat dissipation function according to a fourth embodiment of the present disclosure. Comparing FIG. 14 and FIG. 12, the most obvious difference between the fourth embodiment and the third embodiment is that, in the wireless charging device U with the heat dissipation function provided by the fourth embodiment, the structural design of the case 1 is different from that in the aforementioned embodiment. It should be stated that the structures of the wireless charging assembly 2, the working fluid 3 and the cable assembly 4 are similar to those in the aforementioned embodiment, and will be omitted therein.

Based on the above, referring again to FIG. 13 and FIG. 14, the cable assembly 4 includes the connecting terminal 41. The case 1 includes the first case 11 and the second case 12, and the accommodation space 100 is formed between the first case 11 and the second case 12. In addition, the wireless charging assembly 2 and the cable assembly 4 are disposed on the first case 11 and the connecting terminal 41 is coupled to the connector 23 of the wireless charging assembly 2. Preferably, the package 5 is further provided. The package 5 may cover a portion of the cable assembly 4 and a portion of the first case 11 so that the cable assembly 4 is disposed on the first case 11.

Based on the above, referring again to FIG. 13 and FIG. 14, in the fourth embodiment, the second case 12 includes a bottom plate 121 and a case plate 122 connected with the bottom plate 121 and surrounding the bottom plate 121. The case plate 122 extends toward the first case 11. Preferably, in the fourth embodiment, the bottom plate 121 and the case plate 122 of the second case 12 may be integrally formed. Accordingly, the second case 12 forms a cup-shaped structure to accommodate the working fluid 3 to prevent the working fluid 3 from leaking out. Preferably, the wireless charging assembly 2 is disposed on the first case 11, and the first case 11 is disposed on the case 122. For example, the wireless charging assembly 2 uses a lock fastener (not shown in the drawings) to be locked on the first case 11 or uses a buckle member (not shown in the drawings) to be fixed on the first case 11. Therefore, the first case 11 disposed with the wireless charging assembly 2 can be directly combined with the second case 12 accommodating the working fluid 3 so as to form the wireless charging device U with the heat dissipation function.

Based on the above, it is worth mentioning that the first case 11 and the second case 12 can be combined by a lock fastener (not shown in the drawings). Moreover, in other embodiments, the first case 11 and the second case 12 may be combined by buckling (not shown). Furthermore, in other embodiments, the first case 11 and the second case 12 may be combined by gluing (such as using glue or a tape, not shown in the drawings). The present disclosure is not limited to the manner of combination of the first case 11 and the second case 12, as long as the first case 11 is combined with the second case 12 and the working fluid 3 is prevented from leaking out. It is worth mentioning that in one embodiment, the case plate 122 of the second case 12 may have a guide track (not shown in the drawings) corresponding to the wireless charging assembly 2, so that the wireless charging assembly 2 can slide along the guide track to facilitate the combination of the first case 11 disposed with the wireless charging assembly 2 and the case plate 122 of the second case 12 disposed with the working fluid 3.

One of the beneficial effects of the present disclosure is that, with the technical solution that “the working fluid 3 is disposed in the accommodation space 100 of the case 1 and the circuit board 21 and the coil 22 of the wireless charging assembly 2 are immersed in the working fluid 3,” the wireless charging device U with the heat dissipation function provided by the present disclosure can improve the efficiency in heat dissipation of the wireless charging device U, thereby improving the charging efficiency of the wireless charging device U. Therefore, the heat generated by the wireless charging assembly 2 is quickly transmitted to the case 1 through the working fluid 3. Accordingly, the issue of poor efficiency in wireless charging due to the temperature of the wireless charging device U being too high can be avoided.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A wireless charging device with heat dissipation function, comprising:
a case including an accommodation space;
a wireless charging assembly disposed in the accommodation space and including a circuit board, a coil coupled to the circuit board and a connector coupled to the circuit board; and
a working fluid disposed in the accommodation space of the case, wherein the circuit board and the coil of the wireless charging assembly are immersed in the working fluid.

2. The wireless charging device according to claim 1, wherein the case includes a first case and a second case, and the accommodation space is formed between the first case and the second case.

3. The wireless charging device according to claim 1, further comprising: a cable assembly including a connecting terminal coupled to the connector and a buckle portion near the connecting terminal, wherein the case includes a slot body and a slot, and the slot body is disposed in the slot;
wherein the case further includes a first cover body and a second cover body, the first cover body and the second cover body are disposed in the slot, and the first cover body has an opening slot; wherein the buckle portion of the cable assembly is disposed in the opening slot so that the first cover body is disposed on the cable assembly; and wherein the second cover body is abutted against the first cover body to be indirectly abutted against the cable assembly.

4. The wireless charging device according to claim 1, wherein the case includes a slot body, and the connector of the wireless charging assembly is exposed through the slot body of the case.

5. The wireless charging device according to claim 1, further comprising: a cable assembly and a package, wherein the case includes a slot body and a slot, and the cable assembly passes through the slot body and is coupled to the connector; and wherein the package is disposed in the slot to cover the slot body and a portion of the cable assembly.

6. The wireless charging device according to claim 1, further comprising: a cable assembly, wherein the case includes a slot body and the cable assembly passes through the slot body and is coupled to the connector.

7. The wireless charging device according to claim 1, wherein the working fluid is an insulating liquid.

8. The wireless charging device according to claim 1, further comprising: a cable assembly including a connecting terminal; wherein the case includes a first case and a second case, and the accommodation space is formed between the first case and the second case; and wherein the wireless charging assembly and the cable assembly are disposed on the first case, and the connecting terminal of the cable assembly is coupled to the connector of the wireless charging assembly.

9. The wireless charging device according to claim 8, further comprising: a package, wherein the package covers a portion of the cable assembly and a portion of the first case, so that the cable assembly is disposed on the first case.
